(19) United States
(12) Patent Application Publication
(10) Pub. No.: US 2008/0173476 A1
(43) Pub. Date: Jul. 24, 2008

(54) Embedded waveguide and embedded electromagnetic shielding

(76) Inventor: Martin A. Cotton, Letchworth (GB)

Correspondence Address: DUNLAP CODDING & ROGERS, P.C., PO BOX 16370, OKLAHOMA CITY, OK, 73113, US

(21) Appl. No.: 11/825,169

(22) Filed: Jul. 5, 2007

Related U.S. Application Data
(63) Continuation of application No. 10/046,323, filed on Jan. 14, 2002, now abandoned.
Application No. 10/046,323 is a continuation-in-part of application No. 09/786,787, filed on May 10, 2001, now Pat. No. 6,713,685.
(60) Provisional application No. 60/099,730, filed on Sep. 10, 1998.
(60) Provisional application No. 60/304,088, filed on Jul. 10, 2001.

(51) Int. Cl. H05K 9/00

(52) U.S. Cl. 174/384

(57) ABSTRACT

Construction of printed circuit boards (PCBs) containing electromagnetic shielding and conductive tubes forming signal lines and/or waveguides. The method of construction calls for forming of grooves through layers of the PCB and coating the interior surfaces of these grooves with conductive material. These conductor-coated groove walls serve as conductive surfaces between embedded conductive surfaces on different layers. The conductive surfaces thus joined form a continuous electrically conductive surface that can be configured to act as an electromagnetic shield. Such conductive surfaces may be configured with internal conductors to act as a signal line, or without internal conductors to act as a waveguide.

### CROSS REFERENCE TO RELATED APPLICATIONS

This application is a continuation of U.S. Ser. No. 10/046,323, filed Jan. 14, 2002, which is a continuation-in-part of application U.S. Ser. No. 09/786,787, filed Mar. 9, 2001, now U.S. Pat. No. 6,713,685, which is a U.S. national stage of international application No. PCT/US 99/20418, which claims benefit under 35 U.S.C. § 119(e) of provisional application U.S. Ser. No. 60/099,730, filed Sep. 10, 1998. Each of the 09/786,787 application, the PCT/US 99/20418 international application, and the 60/099,730 provisional application is incorporated by reference herein, in its entirety, for all purposes. Said U.S. Ser. No. 10/046,323 also claims benefit under 35 U.S.C. § 119(e) of provisional application No. 60/304,088, filed Jul. 10, 2001. Each of the applications cited above is incorporated by reference herein, in its entirety, for all purposes.

### INTRODUCTION

The present invention relates generally to the field of printed circuit boards (PCBs). More particularly, the present invention relates to electromagnetic waveguides and electromagnetic shielding structures for multilayer PCBs and the methods for creating such waveguides and structures.

### BACKGROUND OF THE INVENTION

Designers of PCBs have long strived to increase the functionality and component capacity of the PCB. In the pursuit of increased functionality and component capacity, one important enabling factor is how to provide more interconnect traces. These conductive traces go from side to side and from layer to layer and in this way form interconnections between active electronic elements that are mounted on the PCB.

The PCB has throughout its history been made from many alternate materials, using diverse processes. The most common material PCB material in use is a glass-epoxy-based laminate with the PCBs being built in single-sided, double-sided, and even multilayer configurations. The laminate serves as an insulator between the adjacent conductive traces on the surface of the PCB (in single-sided and double-sided configurations), as well as between the multiple layers of conductive traces within the PCB (in multilayer configurations).

Electrical traces on different levels are connected by forming a hole in the laminate between the layers (typically by drilling), and then plating the interior surface of this hole with a conductive material thus joining the traces electrically. The resulting plated barrel of inter layer interconnect is known in the art as a “via.”

Formation of the holes is carried out on a machine employing a mechanical device that rotates and removes material in a circular fashion (i.e., a drill), or by techniques such as laser ablation or plasma etching. Ablation emulates mechanical drilling by creating a more-or-less circular hole in the laminate material.

As data and signal speeds have increased in PCBs, various problems have arisen. One problem is the limitation of a simple conductive trace on the surface of a PCB to carry a signal at the high speeds required. Another problem is the electromagnetic interference between the signals carried on the multiple conductive traces on the same PCB.

Yet another problem is the excessive electromagnetic radiation that emanates from a PCB, which is produced by high-speed signals carried by simple conductive traces on (or in) the PCB. This excessive emanation of electromagnetic radiation is undesirable for two reasons. It is a potential source of interference with other electronic equipment, thus making the PCB a nuisance, or at least running afoul of governmental regulations concerning generation of electromagnetic noise. It is also a security problem since such emanation is susceptible to being intercepted and decoded by hostile parties.

### SUMMARY OF THE INVENTION

It is in view of the above problems that the present invention was developed.

One aspect of the present invention is that it provides a method for carrying higher speed electrical signals in a PCB.

It is another aspect of the present invention that it provides electromagnetic isolation (via shielding) of electrical signals in a PCB from extrinsic influences.

It is also an aspect of the present invention that it provides a way of containing (via shielding) the electromagnetic emissions of an electrical signal in a PCB.

Another aspect of the present invention is a horizontal inductor formed from a conductive tube embedded in a PCB.

The invention manifests these aspects by providing a scheme for constructing PCBs containing electromagnetic shielding and RF waveguides. The method of constructing these shields and waveguides includes cutting grooves between the layers of the PCB and plating the interior surfaces of these grooves with conductive material. These plated grooves then serve as conductive surfaces connecting between embedded conductive surfaces on different layers, much as the via serves as a conductive point between conductive traces on different layers. These conductive surfaces thus joined form a continuous electrically conductive surface closed upon itself. The closed, continuous electrically conductive surface may be configured to act as an electromagnetic shield of any shape, or it may be configured as an elongated conductive tube. The conductive tube may be configured with internal conductors to propagate signals as a coaxial signal line or, alternatively, may be configured without internal conductors to act as a waveguide.

Some of the above aspects of the present invention are manifest in a laminated conductive tube. Some of the above aspects of the present invention are also manifest in a PCB constructed so as to include one more such laminated conductive tube. Aspects of the present invention are also found in a shielded interconnect that provides a Faraday cage for conductors connecting various devices mounted on a PCB. The present invention is also embodied by methods of manufacturing these structures.

Additional objects and advantages of the present invention will be apparent in the following detailed description read in conjunction with the accompanying drawing figures.

### BRIEF DESCRIPTION OF THE DRAWINGS

FIG. 1 illustrates a perspective detail view of the basic structure of the interleaved conductive layers and the conductive trenches used to form conductive tube structures.

FIG. 2 illustrates a cross sectional view of the basic structure of the interleaved conductive layers and the conductive trenches used to form conductive tube structures.

FIGS. 3A-3C illustrates the laser ablation technique employed to construct the trenches in the PCB surface.

FIG. 4 illustrates electromagnetic shielding in a PCB acting as a conductive tube enclosing multiple signal traces.

FIG. 5 illustrates electromagnetic shielding in a PCB acting as a conductive tube enclosing multiple signal traces arranged in differential pairs.

FIG. 6 illustrates a plan view of a contact pad for enabling electrical contact of a surface mounted active device with an embedded conductive tube.

FIG. 7 illustrates a sectional elevation view of a surface mounted active device making electrical contact with an embedded conductive tube.

FIG. 8 illustrates the structure geometry used to fabricate an embedded signal line with an impedance of 50 Ohms.

FIG. 9 illustrates a magnified cross-section of a fabricated signal line.

FIG. 10 illustrates the microscopic structure of the trenching.

FIG. 11 illustrates a perspective detail view of the basic structure of the conductive layers and the conductive trenches used to form conductive tube structures as waveguides.

FIG. 12 illustrates a perspective detail view of the basic structure of a horizontal inductor formed using a conductive tube.

FIG. 13 illustrates a partial section plan view of a Faraday shield constructed to electromagnetically isolate multiple signals in a PCB.

FIG. 14 illustrates a plan view of a PCB having multiple “tiles.”

FIG. 15 illustrates a partial section plan view of a tile-to-tile embedded conductive tube in a PCB, combined with an entire-tile Faraday shield.

### DETAILED DESCRIPTION OF THE INVENTION

The present invention provides a scheme for constructing PCBs containing electromagnetic shielding and RF waveguides. The method of constructing these shields and waveguides includes cutting grooves between the layers of the PCB and forming conductive material on the interior surfaces of these grooves. These conductive groove walls then serve as conductive surfaces connecting between embedded conductive surfaces on different layers, much as the via serves as a conductive point between conductive traces on different layers. These conductive surfaces thus joined form a continuous electrically conductive surface closed upon itself. The closed, continuous electrically conductive surface may be configured to act as an electromagnetic shield of any shape, or it may be configured as an elongated conductive tube. The conductive tube may be configured with internal conductors to propagate signals as a coaxial signal line or, alternatively, may be configured without internal conductors to act as a waveguide.

Shielding structures according to the present invention (particularly conductive tubes) have properties of protecting against external electromagnetic interference, preventing unwanted emanation of signals from inside the structure, impedance matching, and even waveguide propagation. Depending on physical configuration of the shielding structure according to the various embodiments, one or more of these properties may be emphasized over the others.

A laminated signal line according to one embodiment of the present invention has one or more internal conductors, with each of the internal conductors being sandwiched between adjacent layers of non-conducting material. A conductive tube entirely surrounds the internal conductors. The conductive tube is formed by a top conductor layer disposed upon the layers of non-conducting material, a bottom conductor layer disposed below the layers of non-conducting material, and opposed side wall conductors that electrically connect to the top conductor layer and the bottom conductor layer. The opposed side wall conductors are formed by cutting a pair of substantially parallel trenches through the layers of non-conducting material on opposed sides of the internal conductors and plating the walls of the trenches.

A PCB according to another embodiment includes one or more laminated signal lines as described above, or waveguides (conductive tube without internal conductors). The signal lines and waveguides may be formed at a common plane or on diverse planes within the PCB.

A shielded interconnect structure according to yet another embodiment of the present invention provides for interconnection of plural devices on a printed circuit board. The shielded interconnect structure includes first level conductive traces (disposed on an upper surface of the printed circuit board), second level conductive traces (disposed on a buried level of the printed circuit board), and third level conductive traces (disposed on a further buried level of the printed circuit board). Subsequent levels of further buried conductive traces may be used as desired. Each first level conductive trace is adapted for electrical connection to one or more of the plural devices. Micro-vias provide electrical connection from selected ones of the first level conductive traces to selected ones of the second level conductive traces. Buried vias provide electrical connection from the third level conductive traces to certain ones of the second level conductive traces. A conductive shield surrounding the second and third level conductive traces is formed by a top shield layer, a bottom shield layer, and a conductive side wall that electrically connects the top shield layer to the bottom shield layer. The conductive side wall is formed by cutting a trench in the printed circuit board around the internal conductors and plating walls of the trench.

A method according to another embodiment of the present invention provides for formation of a conductive tube in a laminated printed circuit board. The method includes the steps of forming a bottom shield layer on a non-conductive substrate and then forming a first non-conductive layer over the bottom shield layer. An internal conductor (if desired) is then patterned atop the first non-conductive layer, and a second non-conductive layer is formed over the patterned internal conductor and the first non-conductive layer. A top shield layer is formed atop the second non-conductive layer, and a pair of trenches (parallel or otherwise) are formed through the first and second non-conductive layers on opposed sides of the internal conductor. A conductive material is then disposed on walls of the trenches, extending from the bottom shield layer to the top shield layer.

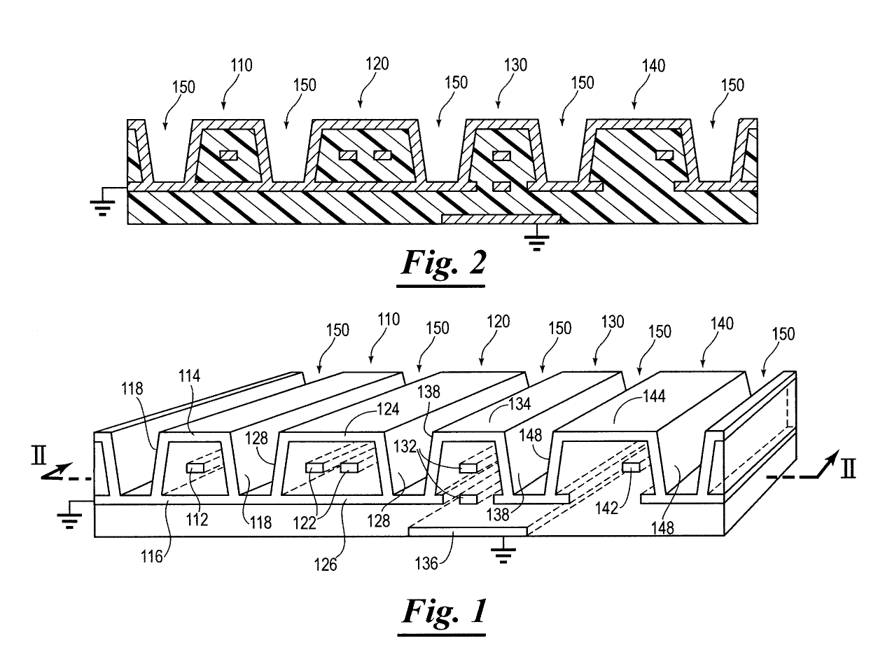

Referring to FIG. 1, a detail perspective view of the basic structure of the interleaved conductive layers and the conductive trenches 150 used to form conductive tube structures is illustrated. Successive layers of conductive materials are patterned and then interleaved with layers of non-conductive material. Connections between conductors on adjacent conductive layers are made by way of plated-through vias that extend through the intervening non-conductive material layer. The non-conductive material employed is not critical and need only satisfy the condition of being compatible with the successive etching steps needed to pattern the conductive layers. It may be homogeneous or inhomogeneous.

A signal line 110 has a single internal conductor 112 that is shielded all around by a conductive tube. The conductive tube is formed by the combination of a top conductive layer 114, a bottom conductive layer 116, and conductive side walls 118 that are each formed onto a side of a conductive trench 150. A signal line 120 has tandem internal conductors 122 that are shielded all around by a conductive tube. The shielding conductive tube is formed by the 360 degree surrounding combination of a top conductive layer 124, a bottom conductive layer 126, and conductive side walls 128 that are each formed onto a side of a conductive trench 150.

The shielding need not be entirely enclosing. A signal line 130 with a pair of stacked conductors 132 is shielded by a top conductive layer 134, a bottom conductive layer 136, and conductive side walls 138 that are each formed onto a side of a conductive trench 150. A signal line 140 with a single internal conductor 142 is shielded on three sides by a top conductive layer 144 and conductive side walls 148 that are each plated onto a side of a conductive trench 150. In the case of these two signal line examples (130, 140), the shielding structure does not close upon itself and, thus, is not strictly a “tube.”

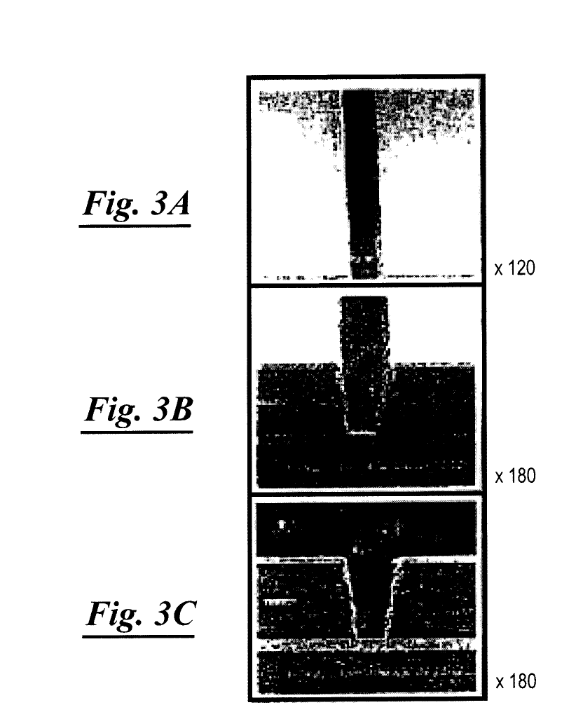

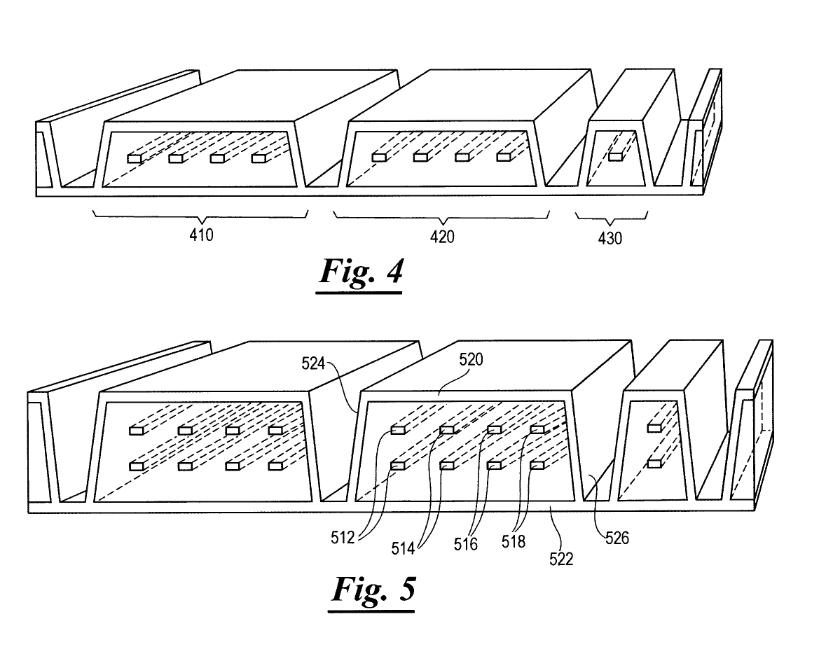

Such almost-tubular embedded shielding structures represent alternate embodiments of the present invention and are understood for the purposes of this application to be included within the meaning of the term “conductive tube” despite the fact that it is not a tube in the strict geometric sense of the word. Although the shielding structure may be embodied so as to have a cross section with one or more discontinuities (similar as FIGS. 3 and 4), it is preferred that the shielding entirely enclose the internal conductors so as to provide the most effective shielding and suppression of cross-talk.

Phantom lines portray embedded contours of the internal conductors and shielding structures. The conductive trenches 150 may be thought of as being non-circular vias with very large aspect ratios.

Referring to FIG. 2, a sectional view of the basic structure of the interleaved conductive layers and the conductive trenches 150 used to form the signal line structures 110, 120, 130, 140 is illustrated. The cross section shows the relative positioning of conductive material being separated from one another by non-conductive material.

Referring to FIGS. 3A-3C, a laser ablation technique employed to construct trenches in a PCB surface is illustrated. The 120× magnification photomicrograph of FIG. 3A shows a plan view of a trench. A cycle ablation mode was employed using a CO₂ laser. Multiple pulses are employed, with each pulse having a pulse width of appropriate the material being ablated, ranging from 5-20 μs. In the example illustrated, a 12 μs pulse width was used. The 180× magnification photomicrograph of FIG. 3B shows the trench from an angle of 45 degrees with respect to the PCB surface, with the PCB being cut away to reveal the cross-sectional structure. The 180× magnification photomicrograph of FIG. 3C shows an elevation view of the trench where the PCB is cut away to reveal the cross-sectional structure.

The present invention is not limited to any specific method of manufacture, though. The laser ablation technique illustrated above is an example of one effective manufacture process. Other techniques based on mechanical machining, plasma etch, and water jet machining are also useful for preparing structures to implement the present invention. Although the manufacturing tolerances that may realistically be achieved will vary between manufacture methods (and between machines), any machine or technique that is capable of forming a trench surface that will yield a sufficiently smooth shielding surface is appropriate for carrying out the present invention.

Referring to FIG. 4, a PCB having electromagnetic shielding formed as a conductive tube enclosing multiple signal traces is illustrated. The conductive tube structures 410, 420, 430 formed according to the principles of the present invention are useful to carry many types of signals. For example, in the context of a computer, one conductive tube 410 can carry data signals, another conductive tube 420 can carry address signals, and yet another conductive tube 430 can carry a clock signal. On the other hand, in the context of a signal analysis system, one conductive tube 410 can carry digital signals, another conductive tube 420 can carry analog signals, and yet another conductive tube 430 can carry a transmit/receive signal. Such conductive tube structures are also useful for carrying various signals in a video-processing environment.

Referring to FIG. 5, electromagnetic shielding in a PCB formed as a conductive tube enclosing multiple signal traces arranged in differential pairs is illustrated. For instance, four differential pairs 512, 514, 516, 518 of elongate conductors are entirely encompassed by a conductive tube shield formed by a top conductive layer 520, a bottom conductive layer 522, and conductive side walls 524, 526 that are each formed onto a side of a conductive trench 530. A differential pairing structure such as this is useful for handling of telecommunication signals.

The multiple conductor examples shown in FIGS. 4 and 5 are specific, concrete examples of how more than one conductive line may be enclosed in a conductive tube shield by way of the present invention. Generally speaking, the present invention is not limited to any particular number of conductors or levels of conductors enclosed within a shield structure. In fact, the present invention may be embodied by a configuration that has no tracks forming internal conductors. Accordingly, a horizontal inductor may be formed using conductive sleeves.

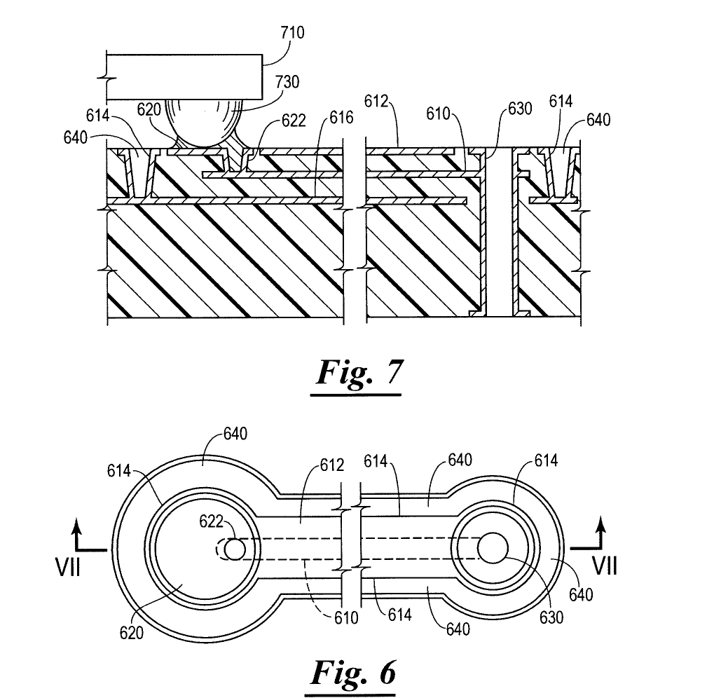

Referring to FIG. 6, a plan view of a contact pad for enabling electrical contact of a surface mounted active device with the internal conductor of an embedded signal line (conductive tube with an internal conductor) is illustrated. A pad 620 is shown where electrical contact may be made. The internal conductor 610 of the embedded signal line (shown in phantom) connects the pad 620 to a plated through hole 630. The pad 620 is connected to the internal conductor 610 by a plated through via 622. The internal conductor 610 is shielded on its top by a top conductive layer 612 and is shielded on its sides by conductive side walls 614 of a surrounding trench 640.

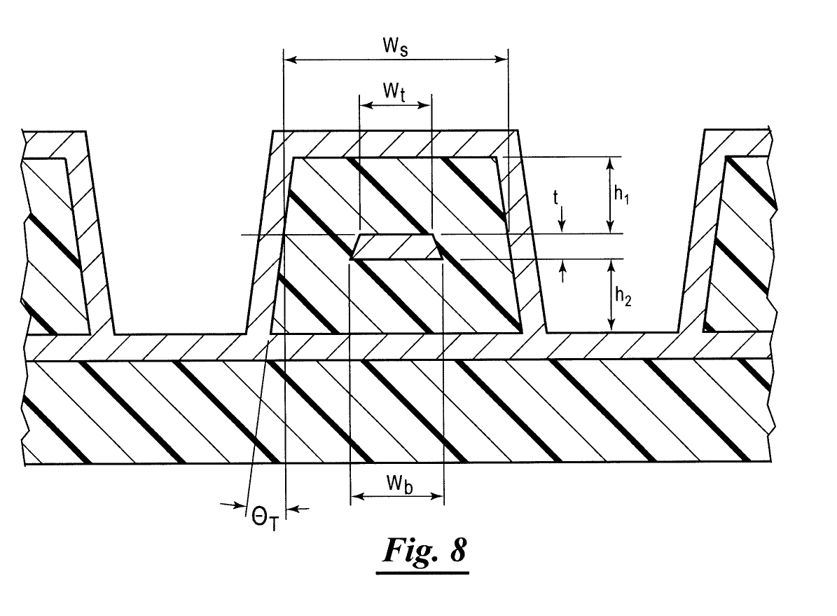

Referring to FIG. 7, a sectional elevation view of a surface mounted active device 710 making electrical contact with an internal conductor of an embedded signal line is illustrated. A ball grid array element 730 is shown solder connected to the pad 620. The internal conductor 610 of the embedded signal line connects the pad 620 to a plated through hole 630. The internal conductor 610 is shielded on its bottom by a lower conductive layer 616.

The structure illustrated in FIGS. 6 and 7 is but an illustrative example of how to connect to an internal conductor of an embedded signal line. Any other connection scheme is encompassed within the concept of the present invention.

### WORKING EXAMPLE

Referring to FIG. 8, the structure geometry used to fabricate an embedded signal line with a nominal impedance of 50 Ohms is illustrated as a working example. The nominal dimensions for the 50 Ohm coaxial signal line are as follows:

t=18 μm

h₁=100 μm

h₂=125 μm

wₜ=75 μm

w_{b}=100 μm

wₛ=400 μm

The nominal width of the trenches is 150 μm. The angle of the trench walls, θ_{T}, which would ideally approach zero, is typically as large as about 10 degrees due to manufacturing expediencies. Assuming the use of Fr4 for the dielectric inside the signal line, the dielectric constant, n, is about 4.6. The calculated impedance for this geometry is 50.6 Ohms. Er is about 4.2.

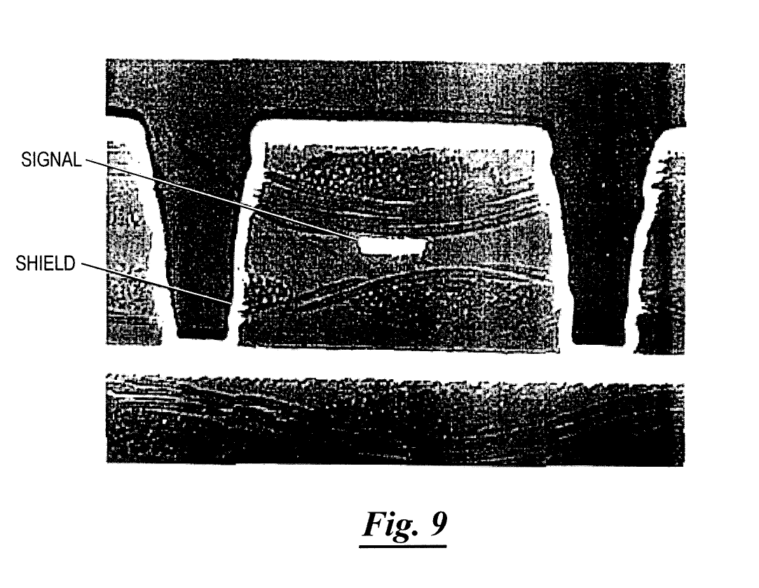

Referring to FIG. 9, a magnified cross-section photomicrograph is illustrated of a working example signal line fabricated from an embedded conductive tube according to the nominal dimensions of FIG. 8. The signal line is shown surrounded entirely by the shield structure. Fr4 material is used to construct the waveguide. For this example, the trenches were formed using a CO₂ laser. The PCB production process (aside from forming the trenches) is accomplished using standard processing techniques as are understood in the art (e.g., Viasystems Mommers or “VSM” techniques).

Signal lines and waveguides constructed likewise to the working example illustrated by FIGS. 8 and 9 may be improved with more careful manufacturing so that the side walls of the conductive tube are more nearly vertical so as to approach the ideal cross-sectional shape of being rectangular (rather than trapezoidal).

The conductive parts of the illustrated shield line and shield structure are formed of copper. Of course, the present invention is not limited to the commonly used metal copper, and may be embodied using any other conductor that lends itself to the lamination process wherein patterned conductive paths are formed between non-conductive layers. For example, tin, tungsten, aluminum, silver, gold, conductive ink, and conductive polymer compositions are all suitable choices. Various methods may be used for applying conductors on an underlying non-conductive layer. Screening, spraying, plating, deposition, and etch of a laminated layer are all useful techniques. These lists are only exemplary and are not exhaustive.

Although the present invention's technique of forming waveguides were developed in the context of small shielded conductors embedded in a printed circuit board, practice of this forming method is not limited to any particular dimensions. The present invention may be practiced to form waveguides of any size.

Although the present invention's technique of forming waveguides were developed in the easy context of forming a flat internal conductors inside an almost square trapezoid, practice of this forming method is not limited to any particular geometry. The present invention may be practiced to form waveguides of any shape by machining trench contours having curved and/or piecewise linear cross section. By making the trenches non-parallel, the shielding may be tapered along its longitudinal axis. As an additional example of geometric diversity, the internal conductors need not run strictly parallel to the walls of the surrounding shielding.

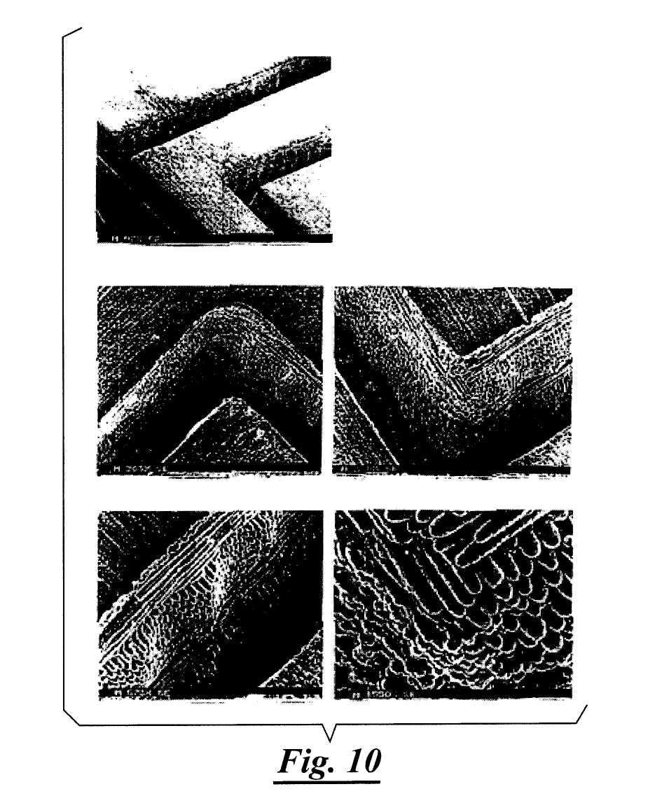

Referring to FIG. 10, the microscopic structure of the trenching is illustrated. A series of five photomicrographs show trench structure according to the present invention at magnifications of 97×, 263×, 388×, 573×, and 1550×.

Referring to FIG. 11, a perspective detail view of the basic structure of the conductive layers and the conductive trenches used to form conductive tube structures as waveguides is illustrated. The conductive tube waveguide 1010 is formed by the combination of a top conductive layer 1014, a bottom conductive layer 1016, and conductive side walls 1018 that are each formed onto a side of a conductive trench 1050. Note the absence of any internal conductor traces within the conductive tube 1010.

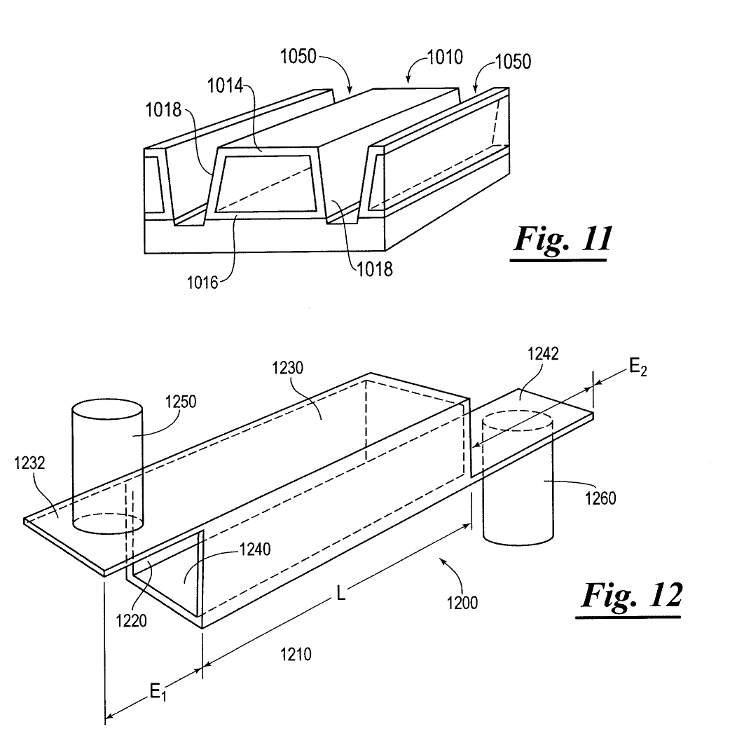

Referring to FIG. 12, a perspective detail view of the basic structure of a horizontal inductor formed using a conductive tube is illustrated. It is expected that the horizontal inductor 1200 would be typically embodied as being buried within layers of a multi-layer PCB. However, for purposes of clarity of illustration, the dielectric material that would surround the horizontal inductor 1200 and fill its core is not shown. The main body of the inductor has a pair of opposed conductive side walls 1210, 1220 with a length L. The side walls 1210, 1220 are each connected between opposed edges of a top conductive layer 1230 and a bottom conductive layer 1240. The inductance of the horizontal inductor 1200 may be selected by varying the length L of its main body.

A portion of the top conductive layer 1230 extends beyond the main body of the inductor as a first end lead 1232 that provides a convenient point for connection to other circuit elements by way of a plated through via 1250. At the other end of the inductor, a portion of the bottom conductive layer 1240 extends beyond the main body of the inductor as a second end lead 1242 that provides a convenient point for connection to other circuit elements by way of a plated through via 1260. The length E₁ of the first end lead 1232 and the length E₂ of the second end lead 1242 may be selected for convenience of arranging a circuit connection as the end leads have negligible affect on the overall inductance of the horizontal inductor 1200.

Using such a construction as illustrated in FIG. 12, a conductive tube is useful as an inductive circuit element.

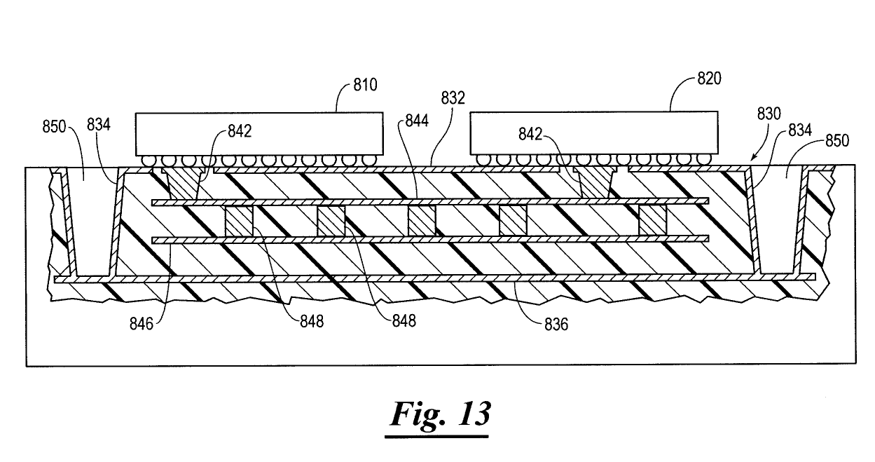

Referring to FIG. 13, a Faraday shield constructed to electromagnetically isolate multiple signals in a PCB is illustrated. Signals between two surface mounted active devices 810, 820 are confined inside a Faraday cage structure 830. Conductive shielding 832 at the top layer is connected to side wall conductors 834 (formed by the plated on side walls of a surrounding trench 850), which is connected to a layer of conductive shielding 836 across the bottom to thereby form the Faraday cage structure 830.

Connections between conductors at the second layer 844 and conductors at the third layer 846 are made using buried via 848 technology. Any connections between conductors at the top layer and conductors at the second and third layers 844, 846 are made using micro-vias 842 from the top layer to the second layer 844. Of course the illustration of only three layers is not intended to be limiting as the Faraday cage structure according to the present invention may shield any number of layers of conductive traces to any depth that may be practically manufactured.

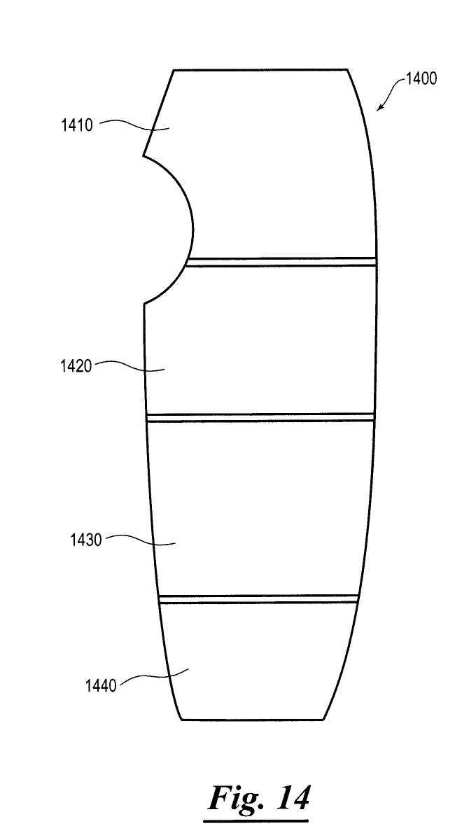

Referring to FIG. 14, a plan view of a PCB 1400 having multiple “tiles” is illustrated. For example, for a mobile telephone PCB, a first tile 1410 would contain RF circuitry, the second tile 1420 would contain digital circuitry, the third tile 1430 would contain analog circuitry, and the fourth tile 1440 would contain power supply circuitry. In other applications, the functional division may be along the lines of left audio/right, or input/output, etc. The tiles 1410, 1420, 1430, 1440 segregate the PCB along functional lines, with the circuitry wiring in each tile is enclosed within a separate Faraday cage structure according to the present invention. This use of Faraday cages for the PCB interconnects of each entire tile minimizes cross-talk between circuits whose interference could easily cause mischief for one another, while permitting them to be integrated tightly adjacent one another.

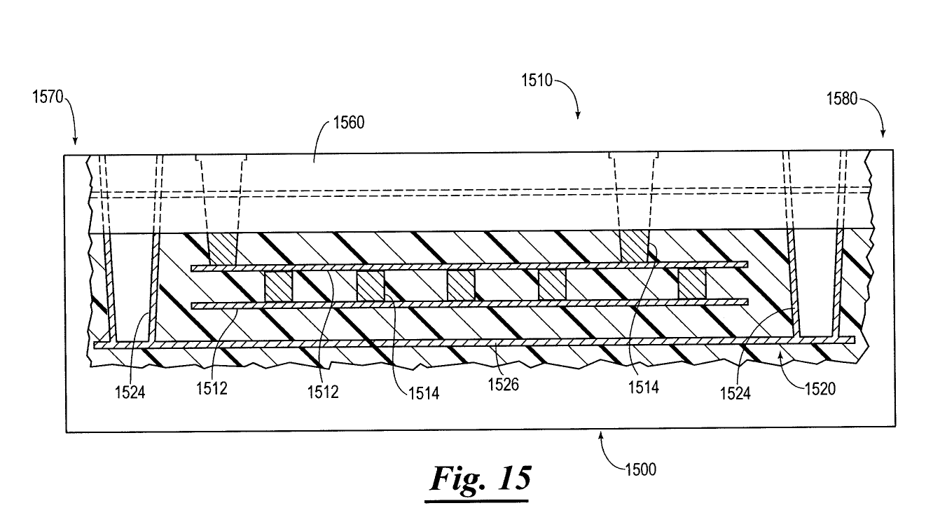

Referring to FIG. 15, a partial section plan view of a tile-to-tile embedded conductive tube in a PCB is illustrated in combination with an entire-tile Faraday shield according to FIG. 14. The printed circuit interconnects 1512 of an entire tile 1510 of the PCB 1500 are shielded by a Faraday cage 1520. Connections between the interconnect layers are made similarly as described in FIG. 13 using vias 1514. The Faraday cage 1520 is formed by top layer conductive shielding (similar to that in FIG. 13) that is connected to side wall conductors 1524 (formed on side walls of a surrounding trench 1550), which are connected to a layer of conductive shielding 1526 across the bottom. A conductive tube 1560 (configured either as a signal line or a waveguide) extends across the tile 1510 to enable shielded coupling of a signal between tiles 1570, 1580 on either side of the tile 1510 traversed by the conductive tube 1560.

The present invention has been described in terms of preferred embodiments, however, it will be appreciated that various modifications and improvements may be made to the described embodiments without departing from the scope of the invention.

What is claimed:

1. A shielded interconnect structure for interconnecting plural devices on a printed circuit board, the shielded interconnect structure comprising:
a plurality of multi-trace signal lines separated by trenches and enclosed within a conductive shield, wherein each multi-trace signal line comprises:
at least one first level conductive trace disposed on an upper surface of the printed circuit board, and adapted for electrical connection to one or more of the plural devices,
at least one second level conductive trace disposed on a buried level of the printed circuit board, and
at least one third level conductive trace disposed on a further buried level of the printed circuit board;
a conductive shield comprising;
a top shield layer disposed on an upper surface of the printed circuit board,
a conductive side wall electrically connected to the top shield layer, and
a bottom shield layer electrically connected to the conductive side wall and buried within the printed circuit board at a level beneath the further buried level; and
a plurality of trenches wherein at least a portion of each trench is parallel to at least one of said multi-trace signal lines and wherein adjacent multi-trace signal lines have at least one of said trenches positioned there between.

2. The shielded interconnect structure of claim 1, wherein the top shield layer, the conductive side wall, and the bottom shield layer are formed so that the conductive shield is a unitary Faraday cage surrounding the plurality of multi-trace signal lines.

3. The shielded interconnect structure of claim 1, wherein the conductive shield and the first, second, and third level conductive traces are formed substantially of copper.

4. The shielded interconnect structure of claim 1 wherein each multi-trace signal line comprises at least one micro-via which connects the at least one first level conductive trace to the at least one second level conductive trace.

5. The shielded interconnect structure of claim 1 wherein each multi-trace signal line comprises at least one micro-via which connects the at least one second level conductive trace to the at least one third level conductive trace.

6. The shielded interconnect structure of claim 1 wherein the conductive side wall of the conductive shield comprises a portion of a wall of at least one of the plurality of trenches.
